(19) United States
(12) Patent Application Publication
(10) Pub. No.: US 2016/0169594 A1
(43) Pub. Date: Jun. 16, 2016

(54) HEATSPREADER WITH EXTENDED SURFACE FOR HEAT TRANSFER THROUGH A SEALED CHASSIS WALL

(71) Applicant: GE INTELLIGENT PLATFORMS, INC., Charlottesville, PA (US)

(72) Inventors: Hendrik Pieter Jacobus DE BOCK, Clifton Park, NY (US); Pramod CHAMARTHY, Boston, MA (US); Shakti Singh CHAUHAN, Niskayuna, NY (US); Tao DENG, Clifton Park, NY (US); Brian HODEN, Niskayuna, NY (US); Stanton Earl WEAVER, Northville, NY (US)

(21) Appl. No.: 14/908,654

(22) PCT Filed: Jul. 29, 2013
(86) PCT No.: PCT/US2013/052488

§ 371 Date: Jan. 29, 2016

(51) Int. Cl. F28F 9/013; F28D 5/00; H05K 7/20; F28F 9/00

(52) U.S. Cl. CPC F28F 9/0138; F28F 9/002; F28D 5/00; H05K 7/20336

(57) ABSTRACT

A system for cooling electronic components. The system includes tubing having a central portion attachable to a heat source disposed within a sealed enclosure. Distal portions of the tubing extend outside the enclosure through walls thereof. The system also includes fins attachable to the distal portions.

### CROSS-REFERENCE TO RELATED APPLICATIONS

This application is a national stage application under 35 U.S.C. §371(c) of prior filed, co-pending PCT application serial number PCT/US2013/052488, filed on Jul. 29, 2013, and titled “HEATSPREADER WITH EXTENDED SURFACE FOR HEAT TRANSFER THROUGH A SEALED CHASSIS WALL”. The above-listed application is herein incorporated by reference.

### TECHNICAL FIELD

Embodiments of the invention relate generally to heat dissipation within an enclosure. More specifically, embodiments of the invention relate to dissipating heat produced by an electronic component mounted on a circuit board within a sealed enclosure.

### BACKGROUND OF THE INVENTION

As the footprint of electronic components continues to decrease, enabling greater numbers of components to be placed on a printed circuit board (PCB), efficiently dissipating heat produced by the components becomes more challenging. This problem is amplified as even more of these PCBs with higher power components are housed within a single enclosure, or chassis.

Traditionally, air is used as the catalyst for dissipating heat and cooling the electronic components electronics within the enclosure. But as the performance demands of these electronic components continues to increase, the traditional heat dissipating approaches become more inefficient and less effective. This ineffectiveness is particularly true in instances where the chassis is sealed from the external environment, which is most often the case where the chassis is used as a line replaceable units (LRU).

For example, one conventional heat dissipation approach includes using fins (e.g., a heat sink) on an outer surface of the chassis itself. That is, since the PCB is affixed to the chassis, either directly or through a mechanical retainment structure, within the enclosure, the fins and the PCB are indirectly connected. This connection, albeit indirect, enables heat to flow from the electronic components (i.e., heat source) on the PCB into the fins—attached to the outside of the chassis. Since positioned external to the chassis, the fins can be cooled by an external air flow.

The aforementioned conventional approach, however, is inefficient and suboptimal. The inefficiencies of this approach render it inadequate to dissipate the massive amounts of heat that accumulate inside of a sealed chassis housing for cutting edge high-performance electronic systems available today.

Another conventional approach includes using heat transfer mechanisms, such as heat pipes, in combination with fins or heat sinks. These other traditional approaches are more suitable for use with exposed systems. These approaches, however, are not designed for use within a sealed system or chassis due to the absence of flow through the system.

FIG. 1 is an illustration of conventional approach for dissipating heat within an exposed system 100. In FIG. 1, a PCB 101 includes various electronic components, including a high performance heat producing, source, such as microprocessor 102. In the conventional system 100, heat pipes 104 are affixed to the PCB 101 and are indirectly connected to the microprocessor 102. The heat pipes 104 are attached to fins 106. As understood by those of skill in the art, fluid evaporates inside the heat pipes 104, as a means of accelerating the dissipation of heat from the PCB 101. The resulting vapor carries the heat through the pipes 106 and to the fins 104, where the heat is dissipated across a surface area of the fins 106 as the vapor condenses back to a fluid.

As depicted, the conventional system 100 is not within a sealed chassis. The conventional system 100 is therefore limited in its utility to dissipate heat created by high performance electronic components housed within modern LRU sealed enclosures.

### BRIEF DESCRIPTION OF THE INVENTION

Given the aforementioned deficiencies, a need exists for methods and systems to dissipate heat, produced by electronic components, within a sealed chassis.

Embodiments of the present invention provide a system for cooling electronic components. The system includes tubing having a central portion attachable to a heat source disposed within a sealed enclosure. Distal portions of the tubing extend outside the enclosure through walls thereof. The system also includes fins attachable to the distal portions.

In the embodiments, an efficient thermal connection is provided through the opening in a wall portion of the sealed enclosure or chassis. As noted above, a heat dissipating electronic component, such as a single board microprocessor, is attached to a PCB disposed within the LRU. A thermal connection can be formed with use of a heat pipe, or some other heat transfer mechanism, for transferring the heat through the pipes, through the wall of the chassis, and into fins outside of the chassis. In this manner, the fins serve as a heat rejection surface.

The embodiments include a seal around the heat pipe allowing for the inside of the chassis to be sealed. Such an arrangement, for example, can meet military ruggedization requirements. Simultaneously, this arrangement can also form an efficient thermal link from the electronic component to the external fins.

The embodiments of the present invention facilitate bypassing of wedgelock thermal resistance and provide improved spreading resistances. These features ultimately result in a higher power dissipation capability of the circuit. They also reduce ambient to junction thermal temperatures of the heat source, or other heat dissipating electronic components, which enhances overall system reliability.

Further features and advantages of the invention, as well as the structure and operation of various embodiments of the invention, are described in detail below with reference to the accompanying drawings. It is noted that the invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS

The accompanying drawings, which are incorporated herein and form part of the specification, illustrate the present invention and, together with the description, further serve to explain the principles of the invention and to enable a person skilled in the relevant art(s) to make and use the invention.

FIG. 1 is an illustration of a conventional heat dissipation system.

FIG. 2 is an illustration of a heat dissipation system constructed and arranged in accordance with embodiments of the present invention.

FIG. 3 is a perspective view of a sealed chassis and heat transfer mechanism used in the embodiment of FIG. 2.

FIG. 4 is an illustration of an exemplary wedlock constructed in accordance with an embodiment of the present invention.

FIG. 5A is an illustration of another exemplary embodiment of the present invention.

FIG. 5B is a more detailed illustration of aspects of the embodiment illustrated in FIG. 5 A.

FIG. 6 is a flowchart of an exemplary method of practicing an embodiment of the present invention.

### DETAILED DESCRIPTION

While the present invention is described herein with illustrative embodiments for particular applications, it should be understood that the invention is not limited thereto. Those skilled in the art with access to the teachings provided herein will recognize additional modifications, applications, and embodiments within the scope thereof and additional fields in which the invention would be of significant utility.

As discussed above, embodiments of the present invention provide a system for dissipating heat within an enclosure. By way of example, and not limitation, the embodiments can include a heat frame, or other efficient thermal connection, between the heat dissipating electronic components on the PCB. An efficient thermal connection is provided from the electronic components, to a heat transfer mechanism, such as heat pipes, through a wall opening of an LRU, to a heat rejection surface, such as a heat sink.

The embodiments also encompass a variety of different heat sink configurations. As explained in greater detail below, the heat sinks, or cold plate attachments, are external to the sealed chassis. Additionally, the embodiments capture sealing configurations for forming the thermal connection through the sealed chassis.

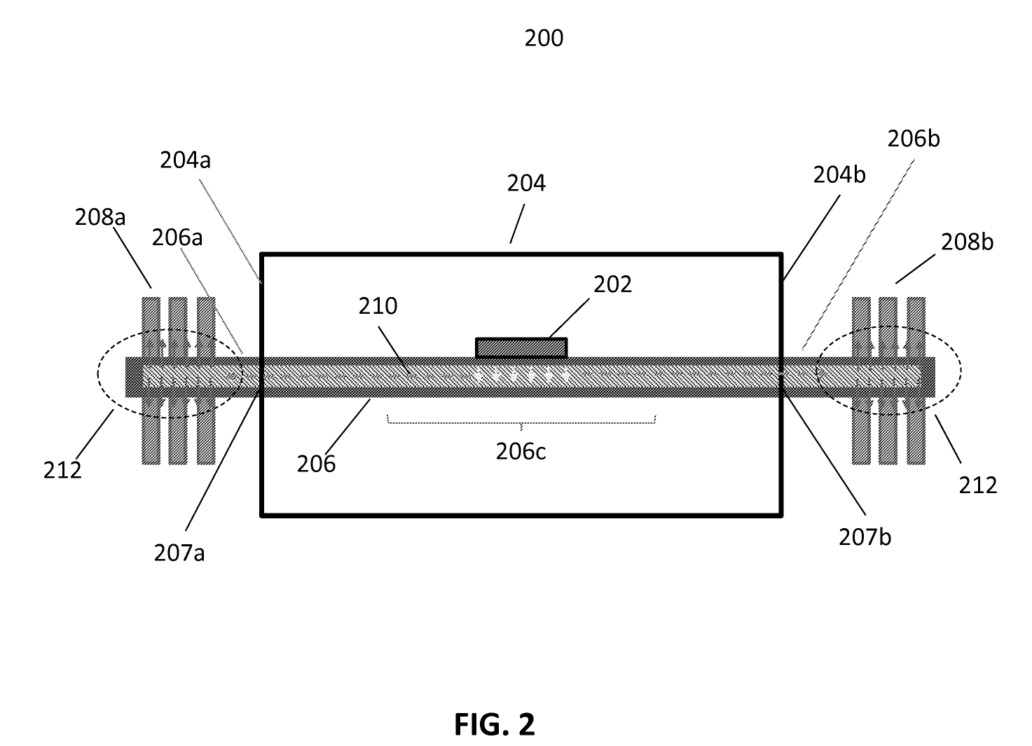

Particular embodiments of the present invention allow for a direct thermal connection between the rejection surface and the heat dissipating components on the PCB. One illustrious embodiment of the present invention is depicted in FIG. 2.

FIG. 2 is an illustration of a heat dissipation system 200 constructed and arranged in accordance with embodiments of the present invention. FIG. 2 depicts a heat source 202 embedded within a sealed chassis 204. By way of example, the sealed chassis 204 could be a flat-panel display, while the heat source 202 could be a microprocessor, an array of active devices, or any other heat producing electrical or electronic component.

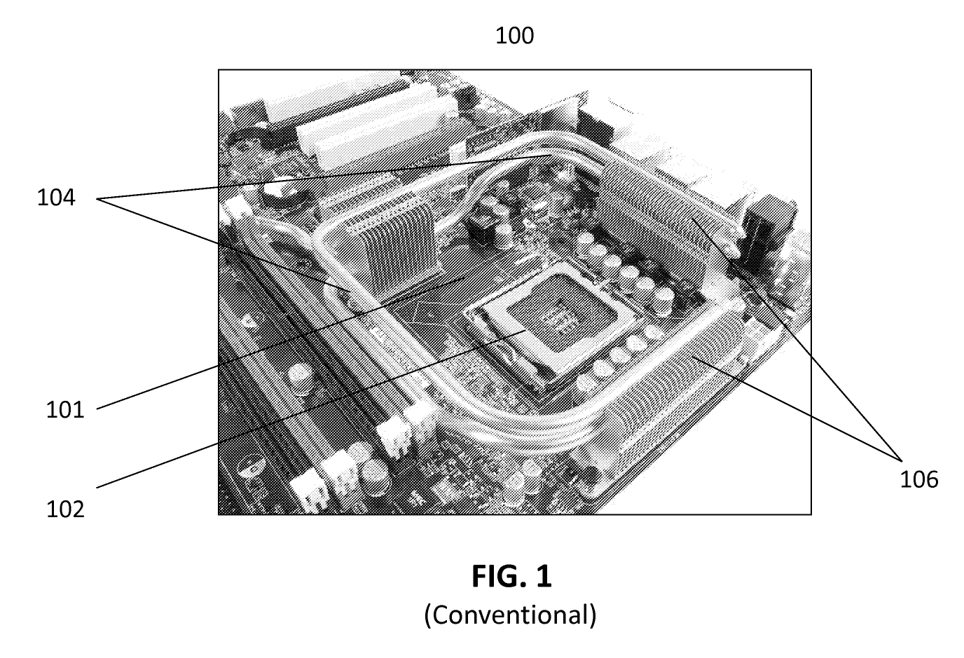

Conventional thermal resistance networks, such as the arrangement 100 of FIG. 1, typically include a convoluted heat path through a wedgelock—eventually spreading through a heat frame and chassis walls.

As understood by those of skill in the art, a wedgelock is a mechanical retainer at the sides of a PCB card that slides into a chassis. Internally it includes a screw that can be torqued to have two or more wedges slide out from the wedgelock which successively retain the card in the chassis.

These conventional approaches, however, do not provide a direct thermal connection between the heat producing component and the heat rejection surface or heat sink. The embodiments of the present invention resolve these deficiencies.

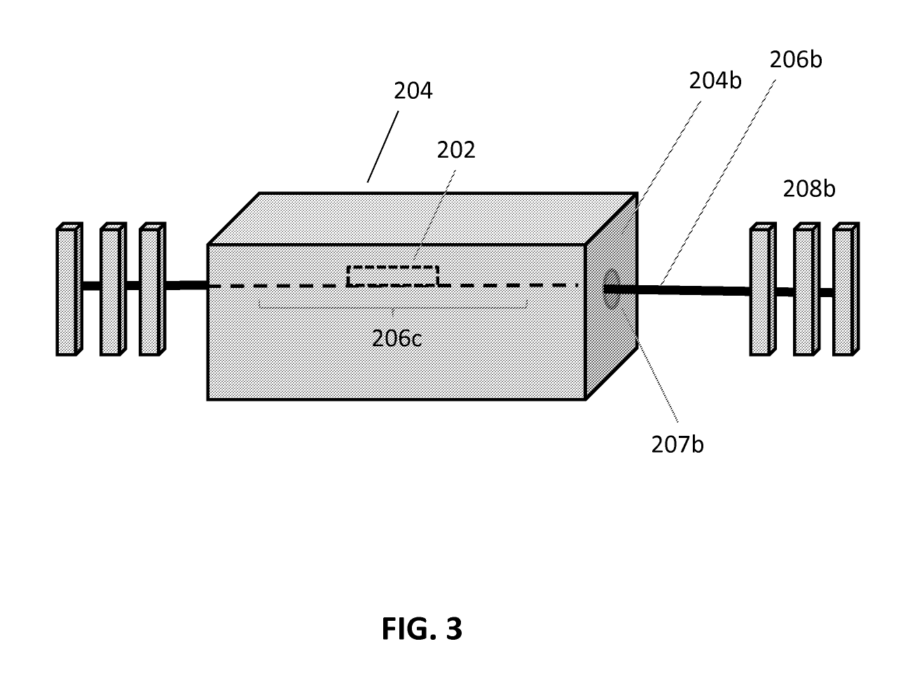

The exemplary system 200 includes a heat transfer mechanism 206 (e.g., a heat pipe structure) having a center portion 206c attached to the heat source 202. Fins 208a/b are respectively attached to distal portions 206a/b of the heat pipe structure 206. The distal portions 206a/b of the heat pipe structure 206 extend through openings 207a/b of wall portions 204a/b of the sealed chassis 204, respectively. FIG. 3 is a more detailed illustration of the connection between one exemplary side of the chassis 204 and the heat pipe structure 206.

FIG. 3 is a perspective view of the chassis 204 and the heat pipe structure 206 of FIG. 2. As shown in FIG. 3, distal portion 206b, of the heat pipe structure 206, extends through respective opening 207b of the wall portion 204b of the chassis 204. Although not shown, the same connection relationships apply to the wall portion 204a, the distal portion 206a, the opening 207a, and the fins 208a.

Returning to FIG. 2, the term sealed as used herein implies that air is unable to freely flow through the chassis. In the exemplary embodiment of FIG. 2, since the chassis 204 is sealed, external air cannot be introduced, by traditional means, to provide cooling of components inside of the chassis. In sealed systems generally, cooling for the heat source cannot be provided by simply allowing air to flow into the chassis from outside. In the embodiments, however, cooling is provided by using a heat transfer mechanism, such as the heat pipe structure 206, and moving heat from inside of the chassis to outside of the chassis using phase change processes within the heat transfer mechanism.

By way of background, and as understood by those of skill in the art, heat transfer mechanisms, such as the heat pipe structure 206, generally include a working fluid, such as fluid 210, which could be water. During operation, the working fluid undergoes a phase change, for example, from liquid to vapor. During the phase change, evaporation occurs when the heat is initially transferred to the heat pipe 206, and into the fluid 210. Condensation occurs and helps facilitate removal of the heat 212 from the pipe 206 via the fins 208a/b.

In the exemplary embodiment of FIG. 2, as noted above, the center portion 206c of the heat pipe 206 is attached the heat source 202. The distal ends of the heat pipe 206a/b pierce respective walls 204a/b of the sealed enclosure 204, via respective openings 207a/b. The openings 207a/b facilitate extension of the heat pipe 206 to an area outside the chassis 204 where air flow can provide cooling.

A tight seal is formed between the wall portions 204a/b and the distal portions 206a/b of the heat pipe 206, via the openings 207a/b, respectively. In the embodiments, the seal formed of the openings 207a/b, between the pipe 206 and the wall 204 simply needs to limit or impede substantial airflow. This seal does not need to be hermetic or even leak proof. That is, there is no limitation on the effectiveness of the seal formed by the extension of the distal portions 206a/b through perspective wall portions 204a/b, through perspective openings 207a/b.

The seal can be implemented in a variety of ways, all within the spirit and scope of the present invention. Seals can be one or more layers of brushes, labyrint seals, rubber spacers, strips. Seal materials can be rubber, Kevlar, metal, polycarbonate, glass fiber, etc.

The process of extending the heat pipe 206 outside of the chassis 204 forms a link. The link connects the heat source 202, within the sealed chassis 204 where air is not available, to outside the chassis where air is available for cooling. The heat transfer mechanism establishes this link. Although embodiments of the present invention implement the heat transfer mechanism using a heat pipe, the present invention is not so limited.

The fins, 208a/b, connected to the respective distal portions 206a/b, facilitate use of air outside of the chassis 204 for cooling the heat source 202. More specifically, the fins 208a/b provide the heat pipe a larger surface area facilitating extraction of the heat by air.

In the embodiments, the shape of the heat pipe 206 can be of any suitable form. For example, the pipe can be circular, rectangular, or other. As understood by those of skill in the art, rectangularly shaped heat pipe configurations are most often used to form vapor chambers.

Additionally, the type of materials used to manufacture the heat transfer system, such as heat pipe 206, can be of any variety. The length of the heat transfer system must simply be sufficient to extend through the walls of the sealed chassis.

Heat dissipation, as achieved through implementation of the various embodiments of the present invention, reduces the overall thermal resistance. This reduction in thermal resistance is due in part to the direct connection between the heat source 202, and the heat transfer mechanism 206 (i.e., the heat pipe). In the embodiments, the requirement of the need for additional heat transfer elements, or other thermal interfaces, has been eliminated.

Consequently, in the embodiments of the present invention, heat transfers into the fins 208a/b directly, since these fins are an extension of the heat pipe 206. This connection process expands the surface area of the heat pipe 206, thereby enhancing its heat dissipation performance.

During operation, the working fluid 210 flows through the heat pipe 206 at a relatively high flow rate. Since the heat source 202 is connected directly to the central portion 206c of the heat pipe 206, the working fluid 210 absorbs the heat from the heat source 202 and evaporates. The resulting vapor, now heated, evacuates the heat through the heat pipe 206 into the distal ends 206a/b. A natural condensation process transfers the heat from the distal ends 206a/b of the pipe, into the fins 208a/b. As shown in FIGS. 2 & 3, the fins 208a/b are exposed to air flowing external to the sealed chassis 204. In this manner, the fins 208a/b facilitate efficient heat dissipation and cooling of the heat source 202.

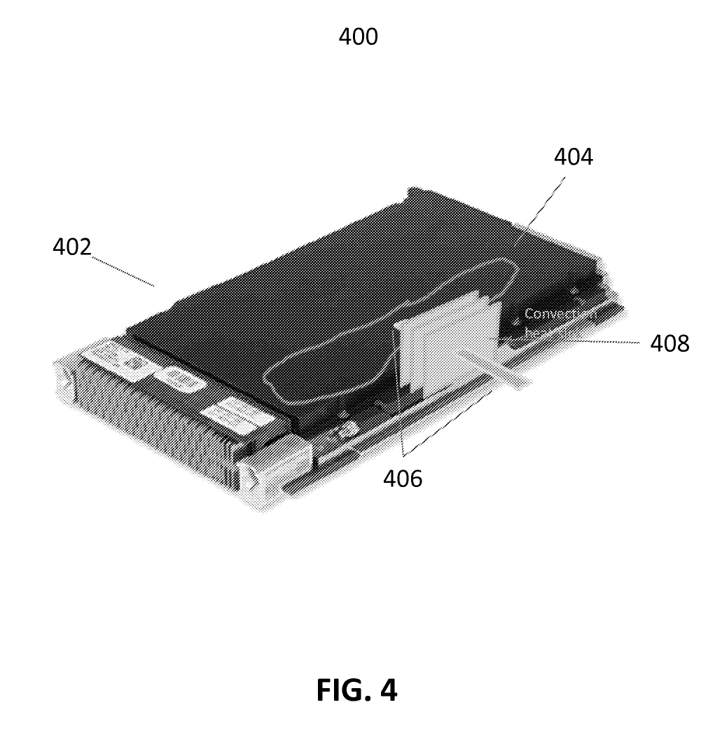

Although FIGS. 2 and 3 depict convection on both sides of the sealed chassis 204, the present invention is not so limited. That is, an embodiment of the present invention can provide convection on only one side of the chassis. FIG. 4 is an exemplary illustration of such an embodiment.

FIG. 4 is an illustration of an exemplary heating assembly 400, constructed in accordance with an embodiment of the present invention, providing convection on a single side of a chassis. In FIG. 4, for example, an aluminum heat spreader installed on a PCB card 402 includes a wedgelock 404. The assembly 400 also includes heat pipes 406, along with fins 408, to facilitate convection and evacuation of the heat. However, in the assembly 400, the heat pipes 406 and the fins 408 are only provided on one side of the heating assembly 400.

In another embodiment, the heat pipe could protrude from a center portion of the wedgelok. In one other illustrious embodiment, the heat pipe can protrude directly from the heat spreader either over, before or after the wedgelock (such as not to interfere with the retaining function). By way of example, PCB cards can be configured for sliding in and out of a chassis. If the heat pipe and the convection heat sink are attached to the PCB card, the seal is more in the form of a slot along the entire length of the chassis. The present invention is not limited to a heat pipe. It could also be a connector of solid material, copper, diamond, carbon nano-tubes, graphene etc.

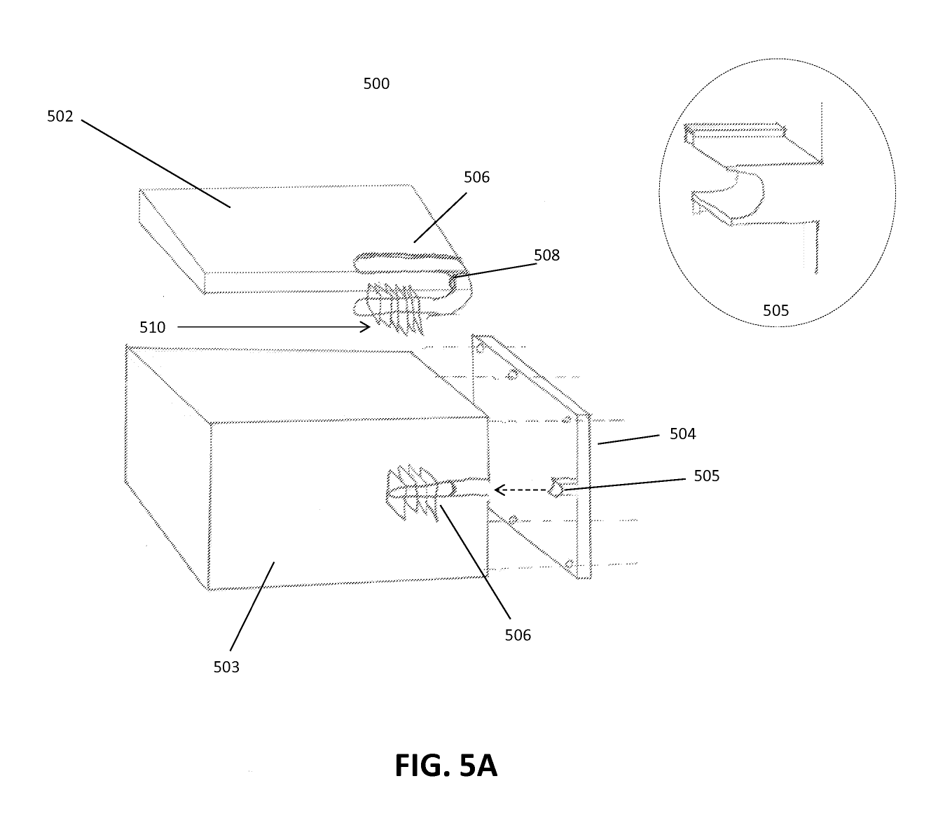

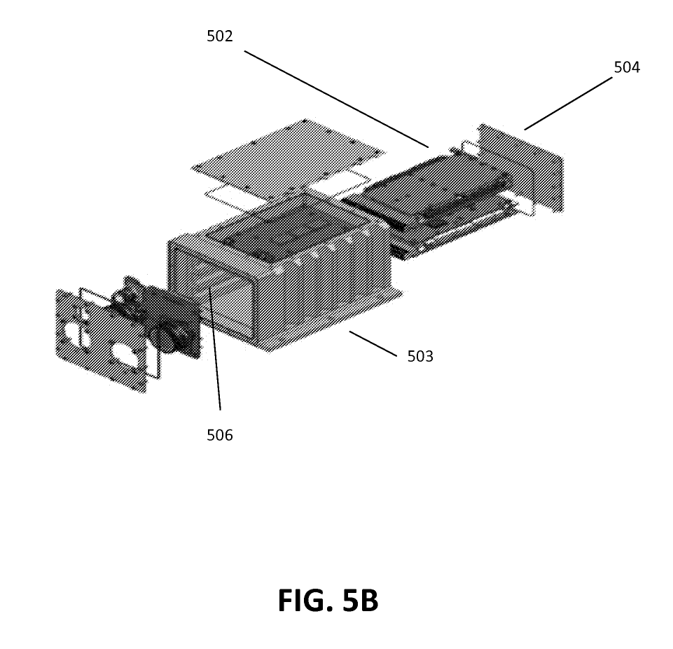

FIG. 5A is an illustration of an assembly 500 representative of another embodiment of the present invention. The assembly 500 includes a conduction cooled heat frame 502 (e.g., a 3U board) configured for insertion into a system chassis 503. The 3U board 502 slides into the chassis 503 on chassis rails (shown below) and is fastened using the wedgelock. During the insertion, the 3U board 502 is sealed within the chassis 503 using a cover 504, including a cover feature 505 (e.g., a half circle cut-out).

FIG. 5B is a more detailed illustration of aspects of the embodiment illustrated in FIG. 5 A. In FIG. 5B, for example, the 3U board 502 slides into the chassis 503 using rails 506. The cover 504 forms a side seal to the chassis 503.

Referring back to FIG. 5 A, a heat pipe 507 is attached to the 3U board 502 and slides into the chassis 503 along the rails 506. The heat pipe 507 can include an O-ring 508 for sealing against the chassis 503, and fins 510. On an opposite side of the heat pipe 507 and the chassis rails 506, the cover feature 505 cut-out fits against the heat pipe 507 to form a side seal. Although in illustration of FIG. 5A, the cover feature 505 is formed of a half circle, other suitable geometries can be used and are within the spirit and scope of the present invention.

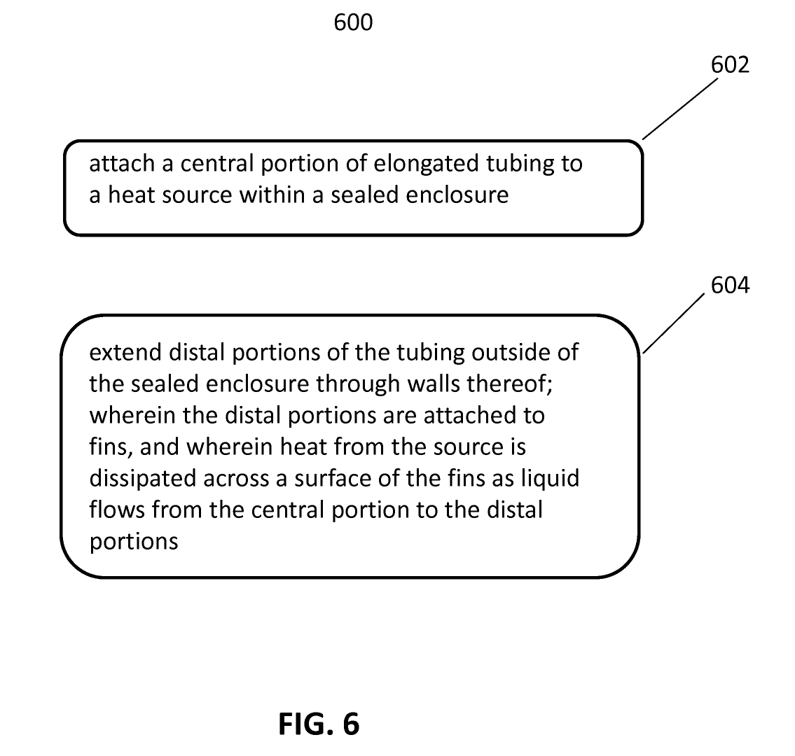

FIG. 6 is a flowchart of an exemplary method 600 of practicing an embodiment of the present invention. In FIG. 6, for example, a step 602 includes attaching a central portion of tubing to a heat source within a sealed enclosure. At step 604, distal portions of the tubing are extended outside of the sealed enclosure through walls thereof. The distal portions are attached to fins, wherein heat from the source is dissipated across a surface of the fins as liquid flows from the central portion to the distal portions.

In the exemplary embodiments, turnkey heat dissipation components can be configured and used to provide heat dissipation inside of a sealed enclosure. Since the major components of the system of the embodiments can be purchased from existing component suppliers, systems, arranged in accordance with the embodiments can be constructed more economically. The heat dissipation process discussed herein, ultimately enhances the power handling capability and the life of the associated LRU's.

The present invention has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

For example, various aspects of the present invention can be implemented by software, firmware, hardware (or hardware represented by software such, as for example, Verilog or hardware description language instructions), or a combination thereof. After reading this description, it will become apparent to a person skilled in the relevant art how to implement the invention using other computer systems and/or computer architectures.

It is to be appreciated that the Detailed Description section, and not the Summary and Abstract sections, is intended to be used to interpret the claims. The Summary and Abstract sections may set forth one or more but not all exemplary embodiments of the present invention as contemplated by the inventor(s), and thus, are not intended to limit the present invention and the appended claims in any way.

1. A system for cooling electronic components, comprising:
a heat transfer device having a central portion attachable to a heat source disposed within a sealed enclosure;
wherein distal portions of the device extend through respective walls of the enclosure; and
fins are attachable to the distal portions.

2. The system of claim 1, wherein the fins form a heat sink.

3. The system of claim 1, wherein the heat transfer device includes heat pipes.

4. The system of claim 1, wherein the heat transfer device includes a vapor chamber.

5. The system of claim 1, wherein the sealed enclosure is hermetically sealed.

6. The system of claim 1, wherein the respective walls include sealable ports, the distal portions of the device extending therethrough.

7. A system for cooling a heat source disposed within a sealed enclosure, comprising:
a heat transfer device attachable to the heat source, distal portions of the device extending through walls of the enclosure via respective sealed ports.

8. The system of claim 7, further comprising fins attachable to the distal portions.

9. The system of claim 7, wherein the heat transfer device includes heat pipes.

10. The system of claim 7, wherein the heat transfer device includes a vapor chamber.

11. The system of claim 7, wherein the fins form a heat sink.

12. A sealable chassis configured for use as a line replaceable unit, comprising:
ports respectively disposed within opposing walls of the chassis;
wherein the ports are configured for extending respective ends of a pipe therethrough.

13. The sealable chassis of claim 12, further comprising connectors for attaching a circuit board therewithin.

14. The sealable chassis of claim 13, wherein the pipe is a heat transfer device; and
wherein the circuit board is configured for mounting an electronic component thereon.

15. The sealable chassis of claim 14, wherein the heat transfer device is connectable to the electronic component.

16. The sealable chassis of claim 12, wherein the sealed enclosure is configured to facilitate transfer of heat from an electronic component mounted therein, to an area external to the enclosure.

17. The sealable chassis of claim 12, wherein the ports are sealable after extending the respective ends of the pipe therethrough.

18. (canceled)

19. (canceled)

20. (canceled)
